(19) United States
(12) Patent Application Publication
(10) Pub. No.: US 2024/0254617 A1
(43) Pub. Date: Aug. 1, 2024

(54) FILM FORMATION METHOD AND FILM FORMATION DEVICE

(71) Applicant: Tokyo Electron Limited, Tokyo (JP)

(72) Inventor: Sena FUJITA, Nirasaki City, Yamanashi (JP)

(21) Appl. No.: 18/564,314

(22) PCT Filed: May 26, 2022
(86) PCT No.: PCT/JP2022/021524

§ 371 Date: Nov. 27, 2023

(30) Foreign Application Priority Data
Jun. 22, 2021 (JP) 2021-093209

(51) Int. Cl. C23C 16/04; C23C 16/50; C23C 16/56; H01J 37/32; H01L 21/306; H01L 21/311; H01L 21/3213

(52) U.S. Cl. CPC C23C 16/04; C23C 16/50; C23C 16/56; H01J 37/32449; H01L 21/306; H01L 21/311; H01L 21/32133; H01J 2237/338

(57) ABSTRACT

A film forming method includes (A) to (C) below. (A) A liquid to a surface of a substrate including a recess and a protrusion, which are adjacent to each other, is supplied on the surface. (B) A processing gas that chemically changes the liquid is supplied to the surface of the substrate to move the liquid from the recess to the protrusion by a reaction between the liquid and the processing gas and to form a film on the top surface of the protrusion, thereby expanding a step difference formed on the surface. (C) A portion of the film is etched.

### TECHNICAL FIELD

The present disclosure relates to a film forming method and a film forming apparatus.

### BACKGROUND

Patent Document 1 discloses a method of selectively depositing a film on a top surface between trenches. In addition, Patent Document 2 discloses a method of selectively forming a film on a specific region of a substrate without using a photolithography technique. This method includes selectively forming a Si adsorption site on a flat surface of the substrate among the flat surface of the substrate and a wall surface of a trench recessed from the flat surface.

### PRIOR ART DOCUMENTS

### Patent Documents

Patent Document 1: Specification of U.S. Pat. No. 10340135

Patent Document 2: Japanese Patent Laid-Open Publication No. 2018-117038

An aspect of the present disclosure provides a technique of expanding a step difference on a surface of a substrate including a recess and a protrusion which are adjacent to each other.

### SUMMARY

A film forming method of an aspect of the present disclosure includes (A) to (C) below. (A) A liquid to a surface of a substrate including a recess and a protrusion, which are adjacent to each other, is supplied on the surface. (B) A processing gas that chemically changes the liquid is supplied to the surface of the substrate to move the liquid from the recess to the protrusion by a reaction between the liquid and the processing gas and to form a film on a top surface of the protrusion, thereby expanding a step difference formed on the surface. (C) A portion of the film is etched.

According to an aspect of the present disclosure, it is possible to expand a step difference on a surface of a substrate including a recess and a protrusion which are adjacent to each other.

### BRIEF DESCRIPTION OF DRAWINGS

FIG. 1 is a flowchart illustrating a film forming method according to an embodiment.

FIG. 2A is a cross-sectional view illustrating an example of step S1.

FIG. 2B is a cross-sectional view illustrating an example of step S2.

FIG. 2C is a cross-sectional view illustrating an example of a first process of step S3.

FIG. 2D is a cross-sectional view illustrating an example of a second process of step S3.

FIG. 3A is a cross-sectional view illustrating an example immediately before step S6.

FIG. 3B is a cross-sectional view illustrating an example immediately after step S6.

FIG. 4A is a cross-sectional view illustrating an example immediately before step S8.

FIG. 4B is a cross-sectional view illustrating an example immediately after step S8.

FIG. 5 is a cross-sectional view illustrating a film forming apparatus according to an embodiment.

FIG. 6A is a SEM photograph of a substrate according to Example 1, taken after step S2 and before step S3.

FIG. 6B is a SEM photograph of the substrate according to Example 1, taken in the middle of step S3.

FIG. 6C is a SEM photograph of the substrate according to Example 1, taken after step S3.

FIG. 7A is a SEM photograph of a substrate according to Example 2, taken after step S2 and before step S3.

FIG. 7B is a SEM photograph of the substrate according to Example 2, taken after step S3.

FIG. 8 is a diagram illustrating the relationship between the processing time in step S9 (Table 2) and the thickness of the liquid in recesses according to Example 3.

FIG. 9A is a SEM photograph of a substrate according to Example 4 after processing.

FIG. 9B is a SEM photograph of a substrate according to Example 5 after processing.

FIG. 9C is a SEM photograph of a substrate according to Example 6 after processing.

FIG. 9D is a SEM photograph of a substrate according to Example 7 after processing.

FIG. 10A is a SEM photograph of a substrate according to Example 8 after processing.

FIG. 10B is a SEM photograph of a substrate according to Example 9 after processing.

FIG. 10C is a SEM photograph of a substrate according to Example 10 after processing.

FIG. 11A is a SEM photograph of a substrate according to Example 11 after processing.

FIG. 11B is a SEM photograph of a substrate according to Example 12 after processing.

FIG. 12A is a SEM photograph of a substrate according to Example 13 after processing.

FIG. 12B is a SEM photograph of a substrate according to Example 14 after processing.

FIG. 13 is a SEM photograph of a substrate according to Example 17 after processing.

FIG. 14 is a SEM photograph of a substrate according to Example 18 after processing.

FIG. 15A is a SEM photograph of a substrate obtained in Example 19 in which the initial depth A0 is 8 nm.

FIG. 15B is a SEM photograph of a substrate obtained in Example 19 in which the initial depth A0 is 12 nm.

FIG. 15C is a SEM photograph of a substrate obtained in Example 19 in which the initial depth A0 is 18 nm.

FIG. 15D is a SEM photograph of a substrate obtained in Example 19 in which the initial depth A0 is 150 nm.

FIG. 16A is a SEM photograph of a substrate obtained in Example 20 in which the initial depth A0 is 8 nm.

FIG. 16B is a SEM photograph of a substrate obtained in Example 20 in which the initial depth A0 is 12 nm.

FIG. 16C is a SEM photograph of a substrate obtained in Example 20 in which the initial depth A0 is 18 nm.

FIG. 17A is a SEM photograph of a substrate obtained in Example 21 in which the initial depth A0 is 8 nm.

FIG. 17B is a SEM photograph of a substrate obtained in Example 21 in which the initial depth A0 is 12 nm.

FIG. 17C is a SEM photograph of a substrate obtained in Example 21 in which the initial depth A0 is 18 nm.

FIG. 18A is a SEM photograph of a substrate obtained in Example 22 in which the initial depth A0 is 8 nm.

FIG. 18B is a SEM photograph of a substrate obtained in Example 22 in which the initial depth A0 is 12 nm.

FIG. 18C is a SEM photograph of a substrate obtained in Example 22 in which the initial depth A0 is 18 nm.

FIG. 18D is a SEM photograph of a substrate obtained in Example 22 in which the initial depth A0 is 150 nm.

FIG. 19A is a SEM photograph of a substrate according to Example 23, showing a state between step S2 and step S3.

FIG. 19B is a SEM photograph of the substrate according to Example 23, showing a state at the completion of step S3.

### DETAILED DESCRIPTION

Hereinafter, embodiments of the present disclosure will be described with reference to the drawings. In each drawing, the same or corresponding components may be denoted by the same reference numerals, and a description thereof may be omitted.

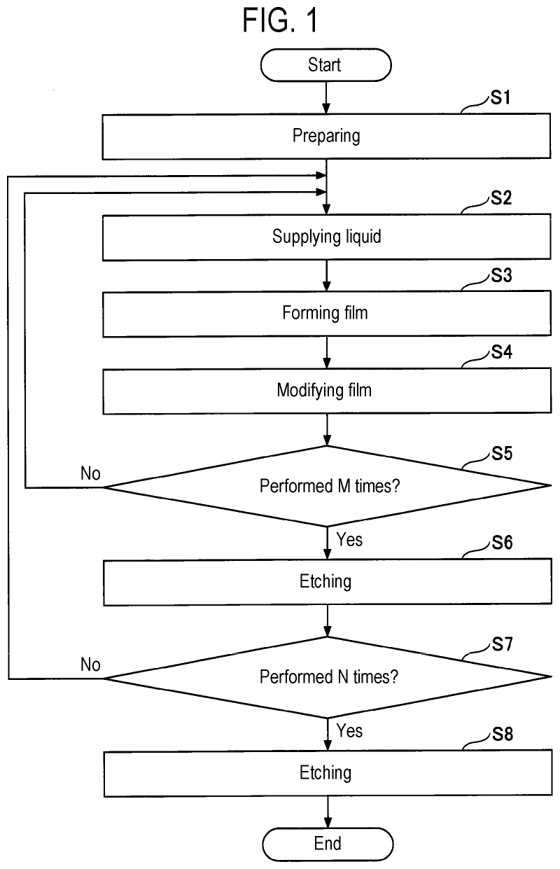

An example of a film forming method will be described with reference to FIG. 1 and the like. As illustrated in FIG. 1, the film forming method includes, for example, steps S1 to S8. The film forming method may include at least steps S1 to S3 and step S6. In addition, the film forming method may further include steps in addition to steps S1 to S8.

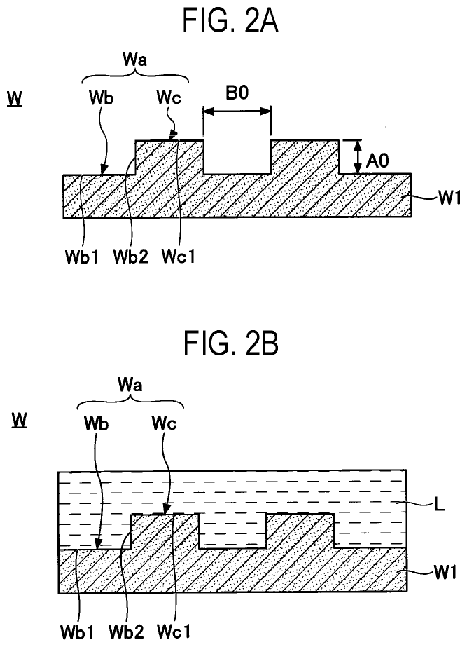

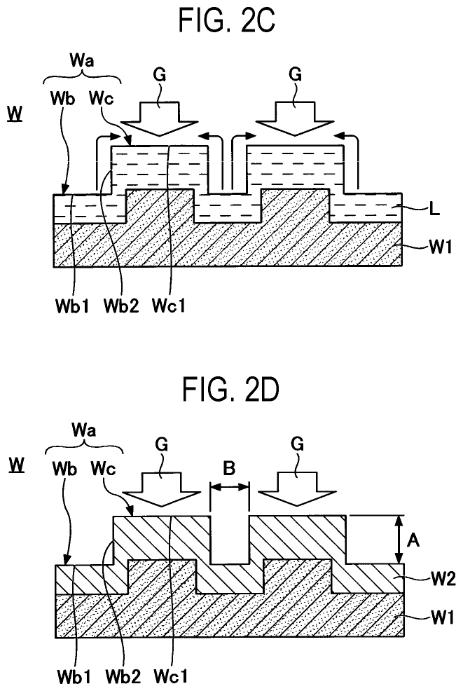

In step S1 of FIG. 1, as illustrated in FIG. 2A, a substrate W including a recess Wb and a protrusion Wc, which are adjacent to each other, on a surface Wa thereof is prepared. Preparing the substrate W includes, for example, loading the substrate W into a processing container 2, which will be described later. The substrate W includes, for example, a silicon wafer W1. The substrate W may include a compound semiconductor wafer or a glass substrate instead of the silicon wafer W1.

The recess Wb and the protrusion Wc are formed, for example, on the surface of the silicon wafer W1. The substrate W may include a film (not illustrated) formed on the surface of the silicon wafer W1, and the film may have a recess Wb and a protrusion Wc. The film may include one or more selected among an insulating film, a conductive film, and a semiconductor film. The recess Wb is a trench, a hole, or the like. The hole includes a via hole. The protrusion Wc may be a pillar, a fin, or the like.

The substrate surface Wa includes, for example, the bottom surface Wb1 of the recess, the side surface Wb2 of the recess, and the top surface Wc1 of the protrusion. For example, the top surface Wc1 of the protrusion is a flat surface, and the recess Wb is recessed from the top surface Wc1 of the protrusion. The depth of the recess Wb represents the size of a step difference.

The initial depth A0 of the recess Wb is, for example, 3 nm to 10,000 nm. The initial width B0 of the recess Wb is, for example, 1 nm to 1,000 nm. The ratio of the initial depth A0 to the initial width B0 (A0/B0) is, for example, 0.05 to 200.

In step S2 of FIG. 1, the liquid L is supplied to the substrate surface Wa, as illustrated in FIG. 2B. The liquid L may cover not only the recess Wb but also the top surface Wc1 of the protrusion. In this case, the surface of the liquid L may be a horizontal surface. In addition, the liquid L may be filled only in the recess Wb and does not need to cover the top surface Wc1 of the protrusion.

The liquid L preferably has strong intermolecular force. As the intermolecular force is increases, so does the cohesive force. When the cohesive force of the liquid L is large, evaporation of the liquid L can be prevented. The intermolecular force of the liquid L is, for example, 30 KJ/mol or more.

The liquid L is, for example, a halide. A liquid halide is formed, for example, by a reaction between a raw material gas of the halide and a reaction gas that reacts with the raw material gas. The production of the liquid L may be promoted by plasmatizing both the raw material gas and the reaction gas, or the reaction gas. The raw material gas is, for example, TiCl₄ gas, and the reaction gas is, for example, H₂ gas.

TiCl₄ gas and H₂ gas are generally used not for forming the liquid L, but for forming a Ti film. The Ti film is formed by, for example, a chemical vapor deposition (CVD) method or an atomic layer deposition (ALD) method. In the CVD method, TiCl₄ gas and H₂ gas are simultaneously supplied to the substrate W. On the other hand, in the ALD method, TiCl₄ gas and H₂ gas are alternately supplied to the substrate W. According to the CVD method or the ALD method, it is estimated that Equations (1) to (3) below contribute to the formation of a Ti film.

$${TiCl}_{4} + {H}_{2} \to {TiH}_{x} {Cl}_{y} \qquad ( 1 )$$

$${TiH}_{x} {Cl}_{y} \to {TiCl}_{2} + HCl \qquad ( 2 )$$

$${TiCl}_{2} + {H}_{2} \to Ti + HCl \qquad ( 3 )$$

In the Equations (2) and (3) above, TiCl₂ may be TiCl or TiCl₃.

In forming a Ti film, the temperature of the substrate W is controlled to 400 degrees C. or higher. As a result, the reactions of Equations (1) to (3) above proceed in sequence, and a Ti film is formed.

On the other hand, in forming the liquid L, the temperature of the substrate W is controlled to −100 degrees C. to 390 degrees C., preferably 20 degrees C. to 350 degrees C. As a result, the reaction of Equation (2) above and the reaction of Equation (3) above are suppressed, so that a liquid L containing TiHₓCl_{y} is formed. The liquid L may contain Ti, TiCl, TiCl₂, TiCl₃, or TiCl₄. The temperature of the substrate W only need to be lower than the decomposition point of the liquid L.

The raw material gas is not limited to TiCl₄ gas. For example, the raw material gas may be a halogenated silicon gas such as SiCl₄ gas, Si₂Cl₆ gas, or SiHCl₃ gas, or a metal halide gas WCl₄ gas, VCl₄ gas, AlCl₃ gas, MoCl₅ gas, SnCl₄ gas, or GeCl₄ gas. The raw material gas only needs to contain halogen, and the halogen may include bromine (Br), iodine (I), fluorine (F), or the like instead of chlorine (Cl). When the temperature of the substrate W is low, a reaction similar to Equation (1) above will mainly proceed with these raw material gases, so that a halide liquid L is formed.

In addition, the reaction gas is not limited to H₂ gas. The reaction gas only needs to be a gas that is capable of forming the liquid L by reaction with the raw material gas. For example, the reaction gas may be D₂ gas. The reaction gas may be supplied together with an inert gas such as argon gas.

Step S2 includes, for example, supplying a raw material gas and a reaction gas to the substrate W at the same time. In this case, step S2 may further include plasmatizing both the raw material gas and the reaction gas. By the plasmatization, the reaction between the raw material gas and the reaction gas can be promoted. In addition, the plasmatization makes it easier to form the liquid L at a low substrate temperature.

In addition, step S2 includes supplying the raw material gas and the reaction gas to the substrate W at the same time in the present embodiment, but may also include supplying the raw material gas and the reaction gas to the substrate W alternately. In the latter case, step S2 may further include plasmatizing the reaction gas. By the plasmatization, the reaction between the raw material gas and the reaction gas can be promoted. In addition, the plasmatization makes it easier to form the liquid L at a low substrate temperature. Furthermore, step S2 may include supplying only the raw material gas to the substrate W.

The liquid L only needs to have strong intermolecular force and may be an ionic liquid, a liquid metal, a liquid polymer, or the like. The metal may be a pure metal or an alloy. The polymer may be, for example, an oligomer or polymer formed by polymerizing two or more molecules of Si₂Cl₆ gas, SiCl₄ gas, SiHCl₃ gas, SiH₂Cl₂ gas, SiH₃Cl gas, SiH₄ gas, Si₂H₆ gas, Si₃H₈ gas, Si₄H₁₀ gas, cyclohexasilane gas, tetraethoxysilane (TEOS) gas, dimethyldiethoxysilane (DMDEOS) gas, 2,4,6,8-tetramethylcyclotetrasiloxane (TMCTS) gas, trisilylamine (TSA) gas, or the like or may be, for example, polysiloxane, polysilane, or polysilazane. In addition, the liquid L may be silanol or the like. These liquids L are supplied to the recess Wb of the substrate W by a spin coating method, or are synthesized inside a processing container that accommodates the substrate W, and is then supplied to the recess Wb of the substrate W.

In step S3 of FIG. 1, a processing gas G that chemically changes the liquid L is supplied to the substrate surface Wa so that the liquid L is moved from the recess Wb to the top surface Wc1 of the protrusion by the reaction between the processing gas G and the liquid L, as illustrated in FIG. 2C, and a film W2 is formed on the top surface Wc1 of the protrusion so that the step difference of the substrate surface Wa is expanded, as illustrated in FIG. 2D. The size of the step difference is represented by the depth A of the recess Wb. By forming the film W2, the depth A of the recess Wb becomes larger than the initial depth A0.

The film W2 may also be formed on the bottom surface Wb1 of the recess. When the thickness of the film W2 on the bottom surface Wb1 of the recess is smaller than the thickness of the film W2 on the top surface Wc1 of the protrusion, the step difference in the substrate surface Wa can be expanded.

The film W2 may also be formed on the side surface Wb2 of the recess. When the thickness of the film W2 on the side surface Wb2 of the recess is smaller than the thickness of the film W2 on the top surface Wc1 of the protrusion, the step difference on the substrate surface Wa can be expanded by forming the film W2, for example, even if the film W2 is isotropically etched.

The thickness of the film W2 on the side surface Wb2 of the recess may be zero. It is sufficient that adjacent side surfaces Wb2 of the recess are not connected to each other and the recess Wb is not closed. This is because if the recess Wb is closed, the step difference will disappear.

The film W2 may be a solid or a viscous body. The thickness of the film W2 can be controlled by the supplied amount of the liquid L.

The processing gas G is supplied, for example, from a space above the substrate surface Wa, and reacts with the liquid L. The liquid L chemically changes by reacting with the processing gas G. Since the chemical change gradually proceeds from the surface of the liquid L, a difference in surface tension occurs, and volumetric expansion or volumetric contraction occurs from the surface of the liquid L, thereby making the liquid L unstable and causing convection. Since the surface of the liquid L changes into a substance with a strong surface tension due to the reaction with the processing gas G, the liquid L moves toward the top surface Wc1 of the protrusion. In addition, the liquid L moves toward the top surface Wc1 of the protrusion by being dragged by the increase and decrease in volume due to the chemical change on the surface of the liquid L. Although not illustrated, all of the liquid L may eventually move to the top surface Wc1 of the protrusion by reaction with the processing gas G.

During the chemical change of the liquid L, degassing occurs from the liquid L due to the reaction between the liquid L and the processing gas G. The movement of the liquid L due to the occurrence of degassing is also considered to be a factor contributing to the movement of the liquid L. In addition, it is considered that minute vibrations of the substrate W may also be a factor contributing to the movement of the liquid L.

The processing gas G contains, for example, elements to be introduced into the liquid L by the reaction with the liquid L. That is, the processing gas G includes elements that are introduced into the film W2. For example, oxygen in the processing gas G is introduced into the liquid L, so that an oxide film W2 is obtained. Alternatively, nitrogen in the processing gas G is introduced into the liquid L, so that a nitride film W2 is obtained. The elements in the processing gas G only need to be introduced into the liquid L, and the elements constituting the liquid L may be degassed during the process.

For example, the processing gas G includes an oxygen-containing gas. The oxygen-containing gas contains oxygen as an element to be introduced into the liquid L. The oxygen-containing gas may further contain nitrogen as an element to be introduced into the liquid L. The oxygen-containing gas includes, for example, O₂ gas, O₃ gas, H₂O gas, NO gas, or N₂O gas.

The processing gas G may include a nitrogen-containing gas. The nitrogen-containing gas includes nitrogen as an element to be introduced into the liquid L. The nitrogen-containing gas includes, for example, N₂ gas, NH₃ gas, N₂H₄ gas, or N₂H₂ gas.

The processing gas G may include a hydride gas. The hydride gas contains, as the element to be introduced into the liquid L, an element bonded to hydrogen, such as Si, Ge, B, C, or P. The hydride gas includes, for example, a hydrocarbon gas such as SiH₄ gas, Si₂H₆ gas, GeH₄ gas, B₂H₆ gas, C₂H₄ gas, or PH₃ gas.

The processing gas G may degas the elements constituting the liquid L by the reaction with the liquid L. For example, the processing gas G includes a reducing gas. The reducing gas is, for example, hydrogen (H₂) gas or deuterium (D₂) gas.

The processing gas G may be supplied together with an inert gas such as argon gas.

Step S3 may include plasmatizing the processing gas G. By the plasmatization, the reaction between the processing gas G and the liquid L can be promoted.

In step S4 in FIG. 1, the film W2 formed in step S3 is modified. The modified film W2 has better chemical resistance than the unmodified film W2. For example, the modified film W2 has a lower etching rate with respect to diluted hydrofluoric acid (DHF) than the unmodified film W2.

The modifying of the film W2 includes, for example, at least one of the following (A) to (B). (A) A halogen element or hydrogen element in the film W2 is reduced. (B) The film W2 is densified. The densification of the film W2 can be achieved, for example, by terminating dangling bonds in the film W2 with an element contained in a modifying gas, or by promoting bonds between existing elements in the film W2.

In step S4, a modifying gas may be supplied to the film W2. When the modifying gas in S4 and the processing gas G in S3 are the same gas, the gases are supplied under different conditions. Specifically, for example, while the modifying gas is plasmatized, the processing gas G is not plasmatized. Alternatively, the modifying gas is supplied at a higher temperature or at a higher pressure than the processing gas G.

However, the modifying gas in S4 and the processing gas G in S3 may be different gases. For example, while the processing gas G is nitrogen gas and is plasmatized, the modifying gas is ammonia (NH₃) gas and is plasmatized, or is hydrazine (N₂H₄) gas. Alternatively, while the process gas G is oxygen (O₂) gas, the modifying gas is ozone (O3) gas or water vapor (H₂O).

In step S5 of FIG. 1, it is confirmed whether the first cycle has been performed M times (M is an integer of 1 or more). One first cycle includes steps S2 to S4 described above. The first cycle may include at least steps S2 and S3, and may not include step S4. M may be an integer of 2 or more.

When the number of times the first cycle has been performed is less than M times (step S5, “NO”), the size of the step difference on the substrate surface Wa is less than a target value, and thus the first cycle is performed again. M is not particularly limited, but is, for example, from 2 to 100, preferably from 5 to 20.

It is sufficient that while the first cycle is performed M times, adjacent side surfaces Wb2 of the recess are not connected to each other and the recess Wb is not closed. This is because if the recess Wb is closed, the step difference will disappear. The upper limit value of M is set so that the recess Wb is not closed.

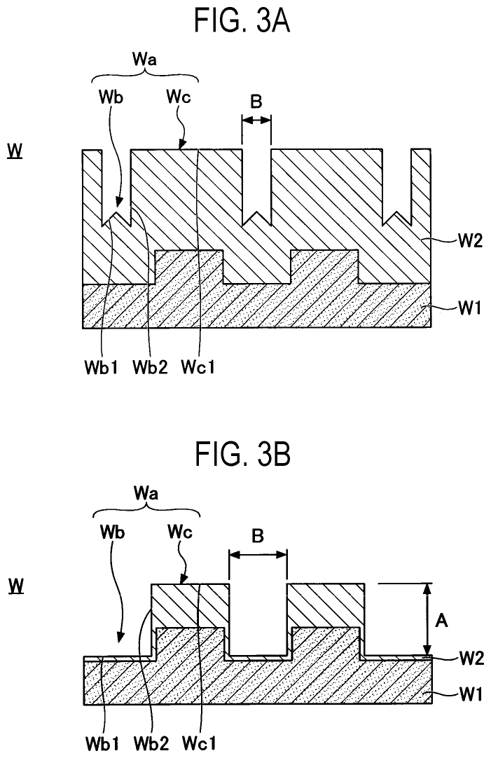

On the other hand, when the number of times the first cycle has been performed reaches M times (step S5, “YES”), the size of the step difference on the substrate surface Wa reaches the target value, and thus the processes of step S6 and subsequent steps are performed. An example of the substrate W immediately before step S6 is illustrated in FIG. 3A.

As illustrated in FIG. 3A, when the first cycle is repeated, the adjacent side surfaces Wb2 of the recess approach each other, and the width B of the recess Wb becomes narrower. Furthermore, when the first cycle is repeated, a protuberance may be formed on the bottom surface Wb1 of the recess.

In step S6 of FIG. 1, a portion of the film W2 is etched. By etching, the width B of the recess Wb can be increased, as illustrated in FIG. 3B. Although not illustrated, the width B of the recess Wb may also be returned to the initial width B0. When the width of the recess Wb is increased by etching, it becomes possible to perform the first cycle again, and further expansion of the step difference becomes possible. It is also possible to remove the protuberance on the bottom surface Wb1 of the recess by etching, as illustrated in FIG. 3B.

Etching may be either isotropic etching or anisotropic etching. Isotropic etching and anisotropic etching may be used in combination. Isotropic etching, which is capable of etching not only the bottom surface Wb1 of the recess and the top surface Wc1 of the protrusion, but also the side surfaces Wb2 of the recess, is effective in increasing the width B of the recess Wb. On the other hand, anisotropic etching is capable of selectively etching the bottom surface Wb1 of the recess and the top surface Wc1 of the protrusion with respect to the side surfaces Wb2 of the recess.

Etching may be either dry etching or wet etching, but dry etching is preferable. In the dry etching, etching gas is supplied to the substrate surface Wa. In the dry etching, H₂ gas, O₂ gas, NH₃ gas, or the like may be supplied to the substrate surface Wa along with the etching gas.

When dry etching is thermal etching, for example, Cl₂ gas, ClF₃ gas, F₂ gas, HF gas, or the like is used as the etching gas. On the other hand, when the dry etching is plasma etching, for example, Cl₂ gas, CF₄ gas, CHF₃ gas, C₄F₈ gas, SF₆ gas, or the like is used as the etching gas to be plasmatized.

In the etching, the etching gas and the reaction gas may be supplied alternately, as in atomic layer etching (ALE). As the etching gas, for example, Cl₂ gas, CF₄ gas, C₄F₈ gas, WF₆ gas, or the like is used. As the reaction gas, Ar gas, He gas, H₂ gas, BCl₃ gas, or the like is used. The reaction gas may be supplied after being plasmatized.

In step S7 of FIG. 1, it is confirmed whether a second cycle has been performed N times (N is an integer of 1 or more). One second cycle includes M times of the first cycle and step S6 performed after the M times of the first cycle. N may be an integer of 2 or more.

When the number of times the second cycle has been performed is less than N times (step S7, “NO”), the size of the step difference on the substrate surface Wa is less than a target value, and thus the second cycle is performed again. N is not particularly limited, but is, for example, from 1 to 10, preferably from 1 to 5.

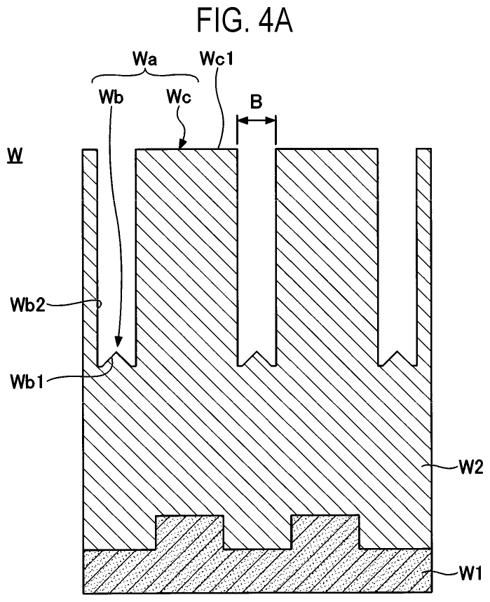

On the other hand, when the number of times the second cycle has been performed reaches N times (step S7, “YES”), the size of the step difference on the substrate surface Wa reaches the target value, and thus the processes of step S8 and subsequent steps are performed. An example of the substrate W immediately before step S8 is illustrated in FIG. 4A.

As illustrated in FIG. 4A, when the second cycle is repeated, the adjacent side surfaces Wb2 of the recess approach each other, and the width B of the recess Wb becomes narrower. Furthermore, when the second cycle is repeated, a protuberance may be formed on the bottom surface Wb1 of the recess.

In step S8 of FIG. 1, a portion of the film W2 is etched like step S6. By etching, the width B of the recess Wb can be increased, as illustrated in FIG. 4B. Although not illustrated, the width B of the recess Wb may also be returned to the initial width B0.

It is also possible to remove the protuberance on the bottom surface Wb1 of the recess by etching, as illustrated in FIG. 4B. In addition, by etching, a material different from the film W2 (e.g., the silicon wafer W1) may be exposed on the bottom surface Wb1 of the recess. Although not illustrated, by etching, a material different from the film W2 (e.g., the silicon wafer W1) may also be exposed on the side surface Wb2 of the recess.

After etching, for example, the bottom surface Wb1 of the recess is formed by the silicon wafer, the side surface Wb2 of the recess is formed by the film W2, and the top surface Wc1 of the protrusion is formed by the film W2. When the width B of the recess Wb is returned to the initial width B0, the side surface Wb2 of the recess is formed by the film W2 and the silicon wafer.

Etching may be either isotropic etching or anisotropic etching. Isotropic etching and anisotropic etching may be used in combination. Isotropic etching, which is capable of etching not only the bottom surface Wb1 of the recess and the top surface Wc1 of the protrusion, but also the side surfaces Wb2 of the recess, is effective in increasing the width B of the recess Wb. On the other hand, anisotropic etching is capable of selectively etching the bottom surface Wb1 of the recess and the top surface Wc1 of the protrusion with respect to the side surfaces Wb2 of the recess.

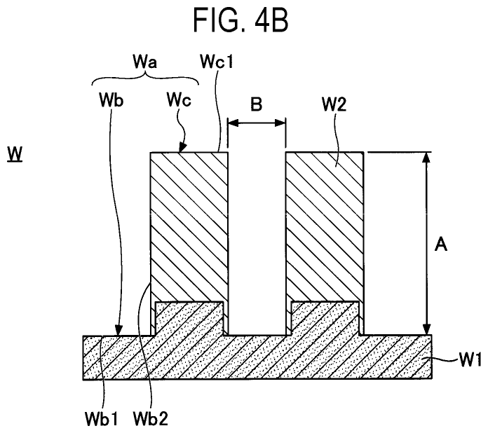

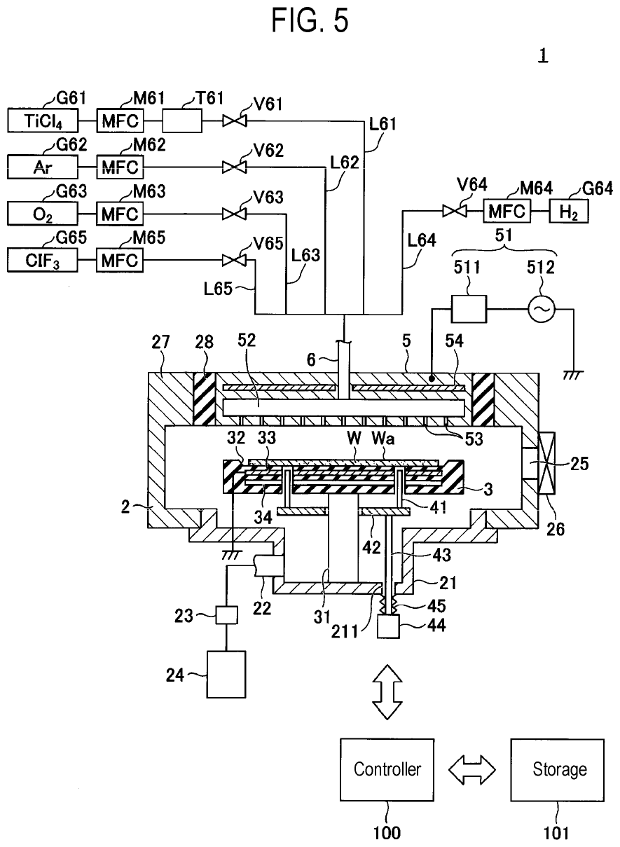

Next, a film forming apparatus 1 will be described with reference to FIG. 5. The film forming apparatus 1 includes a substantially cylindrical and hermetically sealed processing container 2. An exhaust chamber 21 is provided in the central portion of the bottom wall of the processing container 2. The exhaust chamber 21 has, for example, a substantially cylindrical shape that protrudes downward. An exhaust pipe 22 is connected to the exhaust chamber 21, for example, on a side surface of the exhaust chamber 21.

An exhauster 24 is connected to the exhaust pipe 22 via a pressure adjuster 23. The pressure adjuster 23 includes a pressure adjustment valve such as a butterfly valve. The exhaust pipe 22 is configured such that the pressure inside the processing container 2 can be reduced by the exhauster 24. The processing container 2 is provided with a transfer port 25 on its side. The transfer port 25 is opened and closed by a gate valve 26. The loading/unloading of a wafer W between the interior of the processing container 2 and the transfer chamber (not illustrated) is performed through the transfer port 25.

A stage 3 is provided within the processing container 2. The stage 3 is a holder that holds a substrate W horizontally with the surface Wa of the substrate W facing upward. The stage 3 has a substantially circular shape in a plan view and is supported by a support member 31. A substantially circular recess 32 is formed in the surface of the stage 3 to place therein, for example, a substrate W having a diameter of 300 mm. The recess 32 has an inner diameter slightly larger than the diameter of the substrate W. The depth of the recess 32 is substantially the same as, for example, the thickness of the substrate W. The stage 3 is made of a ceramic material such as aluminum nitride (AlN). The stage 3 may be made of a metal material such as nickel (Ni). Instead of the recess 32, a guide ring configured to guide the substrate W may be provided at the peripheral edge of the surface of the stage 3.

For example, a grounded lower electrode 33 is embedded in the stage 3. A heater 34 is embedded below the lower electrode 33. The heater 34 heats the substrate W placed on the stage 3 to a set temperature by receiving power from a power supply (not illustrated) based on a control signal from the controller 100 (see FIG. 5). When the entire stage 3 is made of metal, the entire stage 3 functions as a lower electrode, so that the lower electrode 33 does not have to be embedded in the stage 3. The stage 3 is provided with a plurality of (e.g., three) lifting pins 41 configured to hold and lift the substrate W placed on the stage 3. The material of the lifting pins 41 may be, for example, ceramic such as alumina (Al₂O₃), quartz, or the like. The lower ends of the lifting pins 41 are installed on a support plate 42. The support plate 42 is connected to a lifting mechanism 44 provided outside the processing container 2 via a lifting shaft 43.

The lifting mechanism 44 is installed, for example, under the exhaust chamber 21. A bellows 45 is provided between an opening 211 for the lifting shaft 43 formed in the bottom surface of the exhaust chamber 21 and the lifting mechanism 44. The support plate 42 may have a shape that can be raised/lowered without interfering with the support member 31 of the stage 3. The lifting pins 41 are configured to be raised/lowered by the lifting mechanism 44 between the upper side of the surface of the stage 3 and the lower side of the surface of the stage 3.

A gas supplier 5 is provided on the ceiling wall 27 of the processing container 2 via an insulating member 28. The gas supplier 5 forms an upper electrode and faces the lower electrode 33. A radio-frequency power supply 512 is connected to the gas supplier 5 via a matcher 511. By supplying radio-frequency power of 450 kHz to 2.45 GHz, preferably, 450 KHz to 100 MHZ from the radio-frequency power supply 512 to the upper electrode (the gas supplier 5), a radio-frequency electric field is generated between the upper electrode (the gas supplier 5) and the lower electrode 33 and generates capacitively coupled plasma. A plasma generator 51 includes a matcher 511 and a radio-frequency power supply 512. The plasma generator 51 is not limited to capacitively coupled plasma and may generate other plasma such as inductively coupled plasma.

The gas supplier 5 includes a hollow gas supply chamber 52. In the bottom surface of the gas supply chamber 52, for example, a large number of holes 53 configured to disperse and supply a processing gas into the processing container 2 are evenly arranged. A heater 54 is embedded in the gas supplier 5, for example, above the gas supply chamber 52. The heater 54 is heated to a set temperature by being fed with power from a power supply (not illustrated) based on a control signal from the controller 100.

The gas supply chamber 52 is provided with a gas supply path 6. The gas supply path 6 communicates with the gas supply chamber 52. Gas sources G61, G62, G63, G64, and G65 are connected upstream of the gas supply path 6 via gas lines L61, L62, L63, L64, and L65, respectively.

The gas source G61 is a TiCl₄ gas source, and is connected to the gas supply path 6 via the gas line L61. The gas line L61 is provided with a mass flow controller M61, a storage tank T61, and a valve V61 in that order from the gas source G61 side. The mass flow controller M61 controls the flow rate of TiCl₄ gas flowing through the gas line L61. The storage tank T61 may store the TiCl₄ gas supplied from the gas source G61 via the gas line L61 in the state in which the valve V61 is closed, so that the pressure of the TiCl₄ gas in the storage tank T61 can be increased. The valve V61 supplies and shuts off TiCl₄ gas to/from the gas supply path 6 by opening and closing operations.

The gas source G62 is an Ar gas source, and is connected to the gas supply path 6 via the gas line L62. The gas line L62 is provided with a mass flow controller M62 and a valve V62 in that order from the gas source G62 side. The mass flow controller M62 controls the flow rate of Ar gas flowing through the gas line L62. The valve V62 supplies and shuts off Ar gas to/from the gas supply path 6 by opening and closing operations.

The gas source G63 is an O₂ gas source, and is connected to the gas supply path 6 via the gas line L63. The gas line L63 is provided with a mass flow controller M63 and a valve V63 in that order from the gas source G63 side. The mass flow controller M63 controls the flow rate of O₂ gas flowing through the gas line L63. The valve V63 supplies and shuts off O₂ gas to/from the gas supply path 6 by opening and closing operations.

The gas source G64 is a H₂ gas source, and is connected to the gas supply path 6 via the gas line L64. The gas line L64 is provided with a mass flow controller M64 and a valve V64 in that order from the gas source G64 side. The mass flow controller M64 controls the flow rate of H₂ gas flowing through the gas line L64. The valve V64 supplies and shuts off H₂ gas to/from the gas supply path 6 by opening and closing operations.

The gas source G65 is a ClF₃ gas source, and is connected to the gas supply path 6 via the gas line L65. The gas line L65 is provided with a mass flow controller M65 and a valve V65 in that order from the gas source G65 side. The mass flow controller M65 controls the flow rate of ClF₃ gas flowing through the gas line L65. The valve V65 supplies and shuts off ClF₃ gas to/from the gas supply path 6 by opening and closing operations.

The film forming apparatus 1 includes a controller 100 and a storage 101. The controller 100 includes a CPU, RAM, ROM, and the like (all of which are not illustrated) and controls the film forming apparatus 1 in an integrated manner by causing the CPU to execute, for example, a computer program stored in the ROM or storage 101. Specifically, the controller 100 causes the CPU to execute a control program stored in the storage 101 to control the operation of each component of the film forming apparatus 1, thereby performing a film forming process or the like on a substrate W.

Next, referring again to FIG. 5, the operation of the film forming apparatus 1 will be described. First, the controller 100 opens the gate valve 26 and transfers a substrate W into the processing container 2 and places the substrate W on the stage 3 by the transfer mechanism. The substrate W is placed horizontally with the surface Wa facing upward. The controller 100 causes the transfer mechanism to be retracted from the interior of the processing container 2 and closes the gate valve 26. Next, the controller 100 heats the substrate W to a predetermined temperature by the heater 34 of the stage 3 and adjusts the pressure inside the processing container 2 to a predetermined pressure by the pressure adjuster 23. For example, loading the substrate W into the processing container 2 and the like are included in step S1 in FIG. 1.

Next, in step S2 of FIG. 1, the controller 100 opens the valves V61, V62, and V64, and supplies TiCl₄ gas, Ar gas, and H₂ gas into the processing container 2 at the same time. The valves V63 and V65 are closed. Due to the reaction between the TiCl₄ gas and the H₂ gas, a liquid L such as TiHₓCl_{y} is supplied to the recess Wb of the substrate W.

The specific processing conditions of step S2 are, for example, as follows.

Flow rate of TiCl₄ gas: 1 sccm to 100 sccm

Flow rate of Ar gas: 10 sccm to 100,000 sccm, preferably 100 sccm to 20,000 sccm

Flow rate of H₂ gas: 1 sccm to 50,000 sccm, preferably 10 sccm to 10,000 sccm

Processing time: 1 second to 1,800 seconds

Processing temperature: −100 degrees C. to 390 degrees C., preferably 20 degrees C. to 350 degrees C.

Processing pressure: 0.1 Pa to 10,000 Pa, preferably 0.1 Pa to 2,000 Pa.

In step S2, the controller 100 may generate plasma by the plasma generator 51 to promote the reaction between the TiCl₄ gas and the H₂ gas. When supplying the TiCl₄ gas and the H₂ gas at the same time, the controller 100 plasmatizes both the TiCl₄ gas and the H₂ gas.

In step S2, the controller 100 may alternately supply the TiCl₄ gas and the H₂ gas into the processing container 2 instead of supplying the gases at the same time. In this case, the controller 100 may plasmatize only the H₂ gas among the TiCl₄ gas and the H₂ gas.

After step S2, valves V61 and V64 are closed. At this time, since the valve V62 is open, Ar is supplied into the processing container 2, the gas remaining in the processing container 2 is discharged to the exhaust pipe 22, and the interior of the processing container 2 is replaced with an Ar atmosphere.

Next, in step S3 of FIG. 1, the controller 100 opens the valve V63 and supplies O₂ gas into the processing container 2 together with Ar gas. Due to the reaction between the O₂ gas and the liquid L, the liquid L moves from the recess Wb to the top surface Wc1 of the protrusion, and a film W2 is formed on the top surface Wc1 of the protrusion. As a result, the step difference on the substrate surface Wa is expanded.

The specific processing conditions of step S3 are, for example, as follows.

Flow rate of O₂ gas: 1 sccm to 100,000 sccm, preferably 1 sccm to 10,000 sccm

Flow rate of Ar gas: 10 sccm to 100,000 sccm, preferably 100 sccm to 20,000 sccm

Processing time: 1 second to 1,800 seconds

Processing temperature: −100 degrees C. to 390 degrees C., preferably 20 degrees C. to 350 degrees C.

Processing pressure: 0.1 Pa to 10,000 Pa, preferably 0.1 Pa to 2,000 Pa.

Next, in step S4 of FIG. 1, like step S3, the controller 100 supplies O₂ gas into the processing container 2 together with Ar gas. Furthermore, in step S4, unlike step S3, the controller 100 generates plasma by the plasma generator 51 to modify the film W2. The specific processing conditions of step S4 are the same as those of step S3, except for the generation of plasma, so a description thereof will be omitted.

After step S4, the valve V63 is closed. At this time, since the valve V62 is open, Ar is supplied into the processing container 2, the gas remaining in the processing container 2 is discharged to the exhaust pipe 22, and the interior of the processing container 2 is replaced with an Ar atmosphere.

Next, in step S5 of FIG. 1, the controller 100 confirms whether the first cycle has been performed M times (M is a natural number of 1 or more). One first cycle includes steps S2 to S4 described above. The first cycle may include at least steps S2 and S3, and may not include step S4.

When the number of times the first cycle has been performed is less than M times (step S5, “NO”), the controller 100 performs the first cycle again. On the other hand, when the number of times the first cycle has been performed reaches M times (step S5, “YES”), the controller 100 performs step S6.

Next, in step S6 of FIG. 1, the controller 100 opens the valve V65 and supplies ClF₃ gas into the processing container 2 together with Ar gas. A portion of the film W2 is etched by the ClF₃ gas. In addition, in step S6, the controller 100 may generate plasma by the plasma generator 51, or may plasmatize the ClF₃ gas.

The specific processing conditions of step S6 are, for example, as follows.

Flow rate of ClF₃ gas: 1 sccm to 100 sccm

Flow rate of Ar gas: 10 sccm to 100,000 sccm, preferably 100 sccm to 20,000 sccm

Processing time: 1 second to 1,800 seconds

Processing temperature: 30 degrees C. to 350 degrees C., preferably 80 degrees C. to 200 degrees C.

Processing pressure: 0.1 Pa to 10,000 Pa, preferably 0.1 Pa to 2,000 Pa.

After step S6, the valve V65 is closed. At this time, since the valve V62 is open, Ar is supplied into the processing container 2, the gas remaining in the processing container 2 is discharged to the exhaust pipe 22, and the interior of the processing container 2 is replaced with an Ar atmosphere.

In addition, step S6 and steps S2 to S4 are performed inside the same processing container 2 in the present embodiment, but may be performed inside different processing containers 2.

Next, in step S7 of FIG. 1, the controller 100 confirms whether the second cycle has been performed N times (N is a natural number of 1 or more). One second cycle includes M times of the first cycle and step S6 performed after the M times of the first cycle.

When the number of times the second cycle has been performed is less than N times (step S7, “NO”), the controller 100 performs the second cycle again. On the other hand, when the number of times the second cycle has been performed reaches N times (step S7, “YES”), the controller 100 performs step S8.

Next, in step S8 of FIG. 1, the controller 100 opens the valve V65 and supplies ClF₃ gas into the processing container 2 together with Ar gas. A portion of the film W2 is etched by the ClF₃ gas. In addition, in step S8, the controller 100 may generate plasma by the plasma generator 51, or may plasmatize the ClF₃ gas.

Since the specific processing conditions of step S8 are the same as those of step S6, a description thereof will be omitted. After step S8, the valve V65 is closed. At this time, since the valve V62 is open, Ar is supplied into the processing container 2, the gas remaining in the processing container 2 is discharged to the exhaust pipe 22, and the interior of the processing container 2 is replaced with an Ar atmosphere.

In addition, step S8 and steps S2 to S4 are performed inside the same processing container 2 in the present embodiment, but may be performed inside different processing containers 2.

After step S8, the controller 100 unloads the substrate W from the processing container 2 in a procedure reverse to loading the substrate W into the processing container 2.

### EXAMPLES

Next, examples and the like will be described. Among Examples 1 to 23 below, Examples 1 to 19 and Example 23 are reference examples, and Examples 20 to 22 are examples of the present disclosure. In Examples 1 to 18 and 23 below, before substrates W were loaded into the processing container 2 illustrated in FIG. 5, recesses and protrusions were formed in advance on the substrate surfaces Wa. Hereinafter, the top surfaces Wc1 of the protrusions formed in advance will also be referred to as “protrusion top surfaces Wd”.

### Examples 1 and 2

In Examples 1 and 2, steps S1 to S3 and S5 were performed by using the film forming apparatus 1 illustrated in FIG. 5 under the processing conditions represented in Table 1, and steps S4 and S6 to S8 were not performed.

TABLE 1

| | Protru- | | | Tem- | | | | Other | | | |
|---|---|---|---|---|---|---|---|---|---|---|---|
| | sion | Recess | | perature | | | | sup- | | | Number |
| | top | bottom | | [degrees | | | | plied | | Time | of |
| | surface | surface | Steps | C.] | TiCl₄ | H₂ | Ar | gas | RF | [sec] | Cycles |
| Exam- | SiO₂ | SiO₂ | S2 | 130 | O | O | O | — | ON | 60 | 1 |
| ple 1 | | | S3 | 130 | — | — | O | O₂ | — | 60 | |
| Exam- | SiO₂ | SiO₂ | S2 | 130 | O | O | O | — | ON | 300 | 1 |
| ple 2 | | | S3 | 130 | — | — | O | O₂ | — | 60 | |

In Table 1, the “protrusion top surfaces” is the material of the protrusion top surfaces Wd formed in advance before performing step S2. The material of the side surfaces of the recesses formed in advance before performing step S2 is the same as the material of the protrusion top surfaces Wd. The “recess bottom surfaces” is the material of the bottom surfaces of the recesses formed in advance before performing step S2. In addition, “O” for various gases means that the various gases were supplied, and “ON” for “RF” means that gases was plasmatized by RF power. In addition, the “number of cycles” is the number of repetitions of steps S2 and S3 (that is, M in step S5). The same applies to Tables 2 to 8 which will be described later.

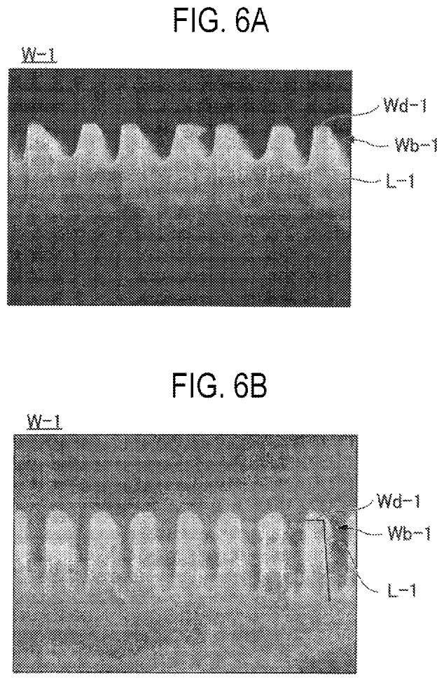

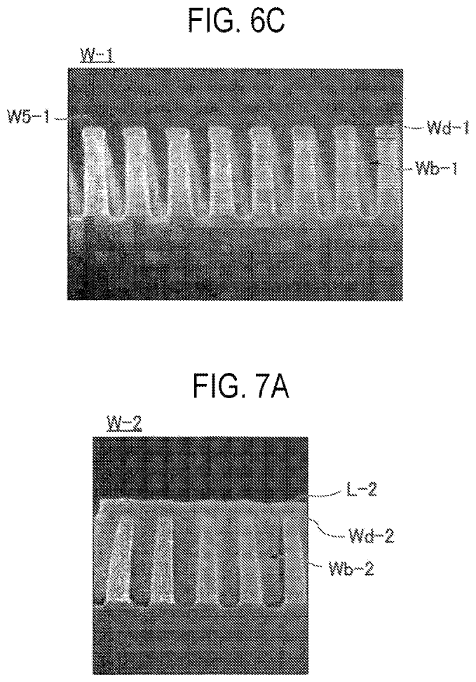

FIGS. 6A to 6C show SEM photographs of a substrate W-1 according to Example 1. As shown in FIG. 6A, the liquid L-1 was supplied to the recesses Wb-1 in step S2. The supplied amount of the liquid L-1 was an amount that allows the liquid L-1 to only enter the interior of the recesses Wb-1. In addition, as shown in FIG. 6B, when the processing was interrupted in the middle of step S3, specifically, when the processing time of step S3 was 10 seconds, a situation similar to FIG. 2C, that is, the situation where the liquid L-1 rose up from the recesses Wb-1 toward the protrusion top surfaces Wd-1 was confirmed. In addition, as shown in FIG. 6C, by step S3, a film W5-1 was selectively formed on the protrusion top surfaces Wd-1.

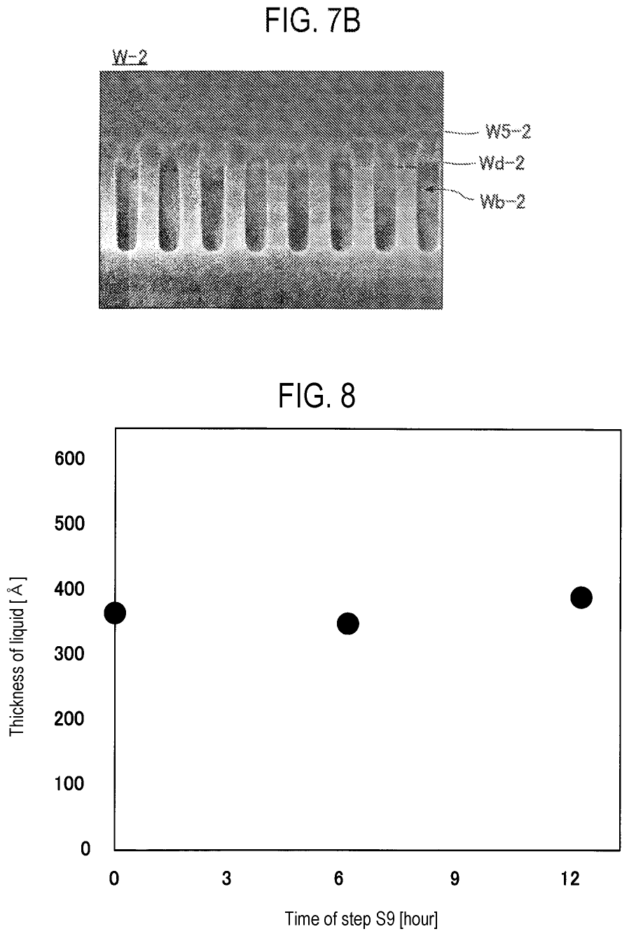

FIGS. 7A and 7B show SEM photographs of a substrate W-2 according to Example 2. As shown in FIG. 7A, the liquid L-2 was supplied to the recesses Wb-2 in step S2. In Example 2, since the processing time in step S2 was longer than that in Example 1 and thus the supplied amount of the liquid L-2 was larger, the liquid L-2 was supplied not only to the recesses Wb-2 but also to the protrusion top surfaces Wd-2. In addition, as shown in FIG. 7B, by step S3, a film W5-2 was selectively formed on the protrusion top surfaces Wd-2.

### Example 3

In Example 3, by using the film forming apparatus 1 shown in FIG. 5, steps S1 to S2 were performed under the processing conditions represented in Table 2, and then step S9 was performed under the processing conditions represented in Table 2 without performing steps S3 to S8. In step S9, only Ar gas was supplied into the processing container 2, and changes in the liquid L in the recesses Wb were observed.

TABLE 2

| | Protru- | | | Tem- | | | | Other | | |
|---|---|---|---|---|---|---|---|---|---|---|
| | sion | Recess | | perature | | | | sup- | | |
| | top | bottom | | [degrees | | | | plied | | Time |
| | surface | surface | Steps | C.] | TiCl₄ | H₂ | Ar | gas | RF | [sec] |
| Exam- | SiO₂ | SiO₂ | S2 | 130 | O | O | O | — | ON | 120 |
| ple 3 | | | S9 | 130 | — | — | O | — | — | — |

FIG. 8 shows the relationship between the processing time in step S9 and the thickness of the liquid L in the recesses Wb according to Example 3. As is clear from FIG. 8, no movement or reduction of the liquid L in the recesses Wb was observed even after being left in a reduced-pressure atmosphere for a long time. This means that the liquid L does not move until the reaction between the liquid L and the processing gas G is initiated, and that the liquid L has strong intermolecular force and strong cohesive force, and therefore is difficult to evaporate.

### Examples 4 to 7

In Examples 4 to 7, steps S1 to S3 and S5 were performed by using the film forming apparatus 1 illustrated in FIG. 5 under the processing conditions represented in Table 3, and steps S4 and S6 to S8 were not performed.

TABLE 3

| | Protru- | | | Tem- | | | | Other | | | |
|---|---|---|---|---|---|---|---|---|---|---|---|
| | sion | Recess | | perature | | | | sup- | | | Number |
| | top | bottom | | [degrees | | | | plied | | Time | of |
| | surface | surface | Steps | C.] | TiCl₄ | H₂ | Ar | gas | RF | [sec] | Cycles |
| Exam- | SiO₂ | SiO₂ | S2 | 130 | O | O | O | — | ON | 120 | 1 |
| ple 4 | | | S3 | 130 | — | — | O | O | — | 120 | |
| Exam- | SiO₂ | SiO₂ | S2 | 130 | O | O | O | — | ON | 10 | 10 |
| ple 5 | | | S3 | 130 | — | — | O | O₂ | — | 60 | |
| Exam- | SiO₂ | SiO₂ | S2 | 130 | O | O | O | — | ON | 10 | 10 |
| ple 6 | | | S3 | 130 | — | — | O | H₂O | — | 60 | |
| Exam- | SiO₂ | SiO₂ | S2 | 130 | O | O | O | — | ON | 10 | 10 |
| ple 7 | | | S3 | 130 | — | — | O | N₂ | ON— | 10 | |

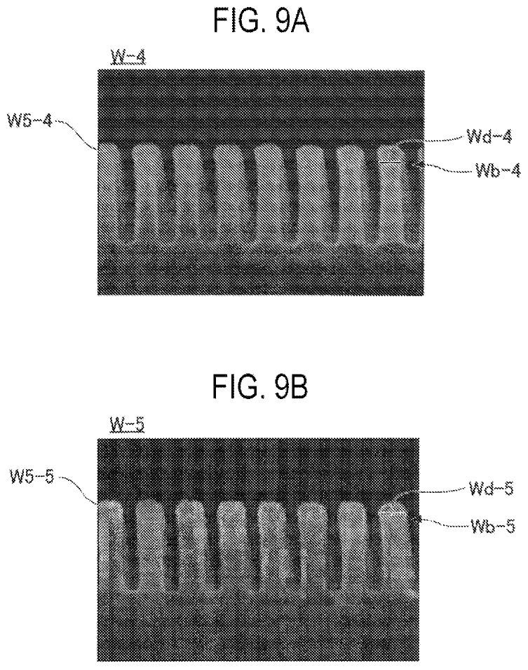

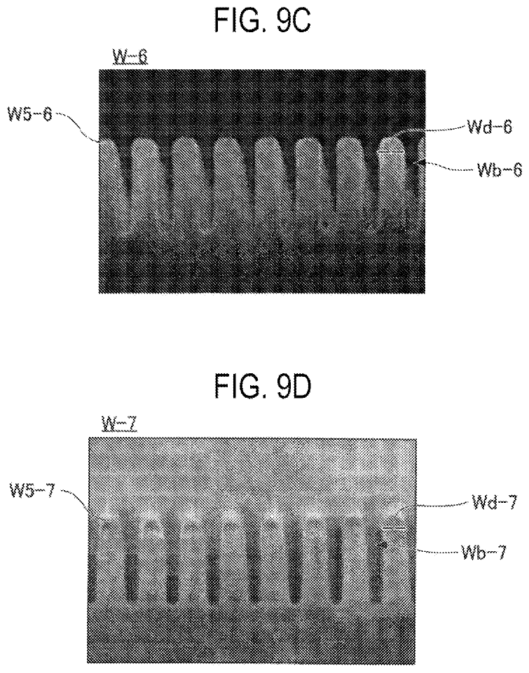

FIG. 9A shows a SEM photograph of a substrate W-4 according to Example 4 after processing. In Example 4, like Example 1, step S2 and step S3 were performed once each. As a result, a film W5-4 was selectively formed on the protrusion top surfaces Wd-4 among the recesses Wb-4 and the protrusion top surfaces Wd-4.

FIG. 9B shows a SEM photograph of a substrate W-5 according to Example 5 after processing. In Example 5, unlike Example 1, steps S2 and S3 were performed 10 times each. As a result, a film W5-5 was selectively formed on the protrusion top surfaces Wd-5 among the recesses Wb-5 and the protrusion top surfaces Wd-5.

FIG. 9C shows a SEM photograph of a substrate W-6 according to Example 6 after processing. In Example 6, unlike Example 1, H₂O gas was supplied into the processing container 2 instead of O₂ gas in step S3. As a result, a film W5-6 was selectively formed on the protrusion top surfaces Wd-6 among the recesses Wb-6 and the protrusion top surfaces Wd-6.

FIG. 9D shows a SEM photograph of a substrate W-7 according to Example 7 after processing. In Example 7, unlike Example 1, N₂ gas was supplied into the processing container 2 instead of O₂ gas in step S3. In addition, the N₂ gas was plasmatized. As a result, a film W5-7 was selectively formed on the protrusion top surfaces Wd-7 among the recesses Wb-7 and the protrusion top surfaces Wd-7.

As is clear from Examples 4 to 7, it was possible to selectively form films W5 on the protrusion top surfaces Wd by using various types of processing gases G.

### Examples 8 to 12

In Examples 8 to 12, steps S1 to S3 and S5 were performed by using the film forming apparatus 1 illustrated in FIG. 5 under the processing conditions represented in Table 4, and steps S4 and S6 to S8 were not performed.

TABLE 4

| | Protru- | | | Tem- | | | | Other | | | |
|---|---|---|---|---|---|---|---|---|---|---|---|
| | sion | Recess | | perature | | | | sup- | | | Number |
| | top | bottom | | [degrees | | | | plied | | Time | of |
| | surface | surface | Steps | C.] | TiCl₄ | H₂ | Ar | gas | RF | [sec] | Cycles |
| Exam- | TiO₂ | TiO₂ | S2 | 130 | O | O | O | — | ON | 120 | 1 |
| ple 8 | | | S3 | 130 | — | — | O | O₂ | — | 120 | |
| Exam- | SiN | SiN | S2 | 130 | O | O | O | — | ON | 120 | 1 |
| ple 9 | | | S3 | 130 | — | — | O | O₂ | — | 120 | |
| Exam- | Si | Si | S2 | 130 | O | O | O | — | ON | 120 | 1 |
| ple 10 | | | S3 | 130 | — | — | O | O₂ | — | 120 | |
| Exam- | C | C | S2 | 130 | O | O | O | — | ON | 120 | 1 |
| ple 11 | | | S3 | 130 | — | — | O | O₂ | — | 120 | |
| Exam- | Ru | SiO₂ | S2 | 130 | O | O | O | — | ON | 120 | 1 |
| ple 12 | | | S3 | 130 | — | — | O | O₂ | — | 120 | |

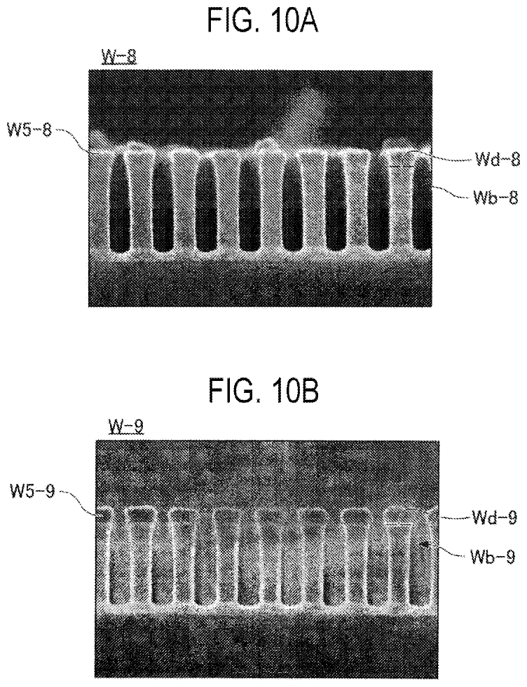

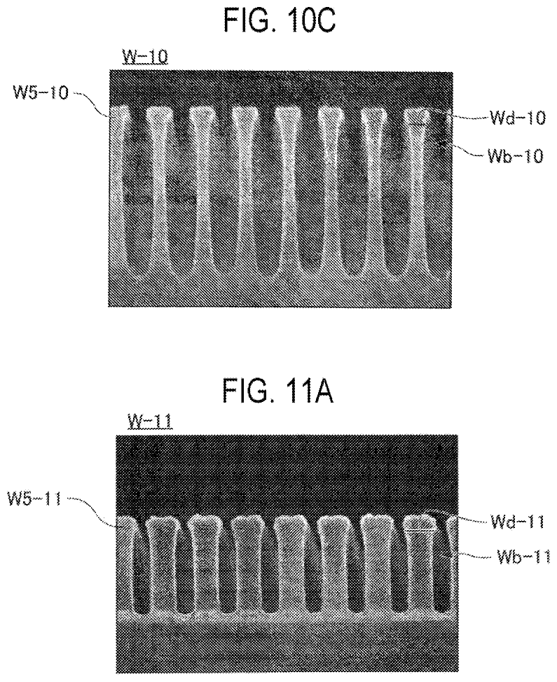

FIG. 10A shows a SEM photograph of a substrate W-8 according to Example 8 after processing. In Example 8, steps S2 and S3 were performed once each under the same conditions as Example 4, except that the material of the protrusion top surfaces and the recess bottom surfaces was changed to titanium oxide (TiO₂). As a result, a film W5-8 was selectively formed on the protrusion top surfaces Wd-8 among the recesses Wb-8 and the protrusion top surfaces Wd-8.

FIG. 10B shows a SEM photograph of a substrate W-9 according to Example 9 after processing. In Example 9, steps S2 and S3 were performed once each under the same conditions as Example 4, except that the material of the protrusion top surfaces and the recess bottom surfaces was changed to silicon nitride (SiN). As a result, a film W5-9 was selectively formed on the protrusion top surfaces Wd-9 among the recesses Wb-9 and the protrusion top surfaces Wd-9.

FIG. 10C shows a SEM photograph of a substrate W-10 according to Example 10 after processing. In Example 10, steps S2 and S3 were performed once each under the same conditions as Example 4, except that the material of the protrusion top surfaces and the recess bottom surfaces was changed to silicon (Si). As a result, a film W5-10 was selectively formed on the protrusion top surfaces Wd-10 among the recesses Wb-10 and the protrusion top surfaces Wd-10.

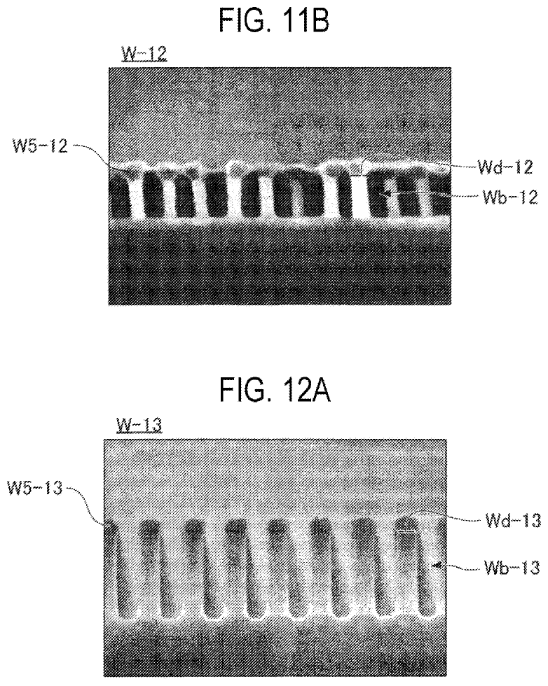

FIG. 11A shows a SEM photograph of a substrate W-11 according to Example 11 after processing. In Example 11, steps S2 and S3 were performed once each under the same conditions as Example 4, except that the material of the protrusion top surfaces and the recess bottom surfaces was changed to carbon (C). As a result, a film W5-11 was selectively formed on the protrusion top surfaces Wd-11 among the recesses Wb-11 and the protrusion top surfaces Wd-11.

FIG. 11B shows a SEM photograph of a substrate W-12 according to Example 12 after processing. In Example 12, steps S2 and S3 were performed once each under the same conditions as Example 4, except that the material of the protrusion top surfaces was changed to ruthenium (Ru). As a result, a film W5-12 was selectively formed on the protrusion top surfaces Wd-12 among the recesses Wb-12 and the protrusion top surfaces Wd-12.

As is clear from Examples 8 to 12, it was possible to selectively form films W5 on the protrusion top surfaces Wd by using substrates made of various materials.

### Examples 13 to 14

In Examples 13 to 14, steps S1 to S3 and S5 were performed by using the film forming apparatus 1 illustrated in FIG. 5 under the processing conditions represented in Table 5, and steps S4 and S6 to S8 were not performed.

TABLE 5

| | Protru- | | | Tem- | | | | Other | | | |
|---|---|---|---|---|---|---|---|---|---|---|---|
| | sion | Recess | | perature | | | | sup- | | | Number |
| | top | bottom | | [degrees | | | | plied | | Time | of |
| | surface | surface | Steps | C.] | TiCl₄ | H₂ | Ar | gas | RF | [sec] | Cycles |
| Exam- | SiO₂ | SiO₂ | S2 | 80 | O | O | O | — | ON | 120 | 1 |
| ple 13 | | | S3 | 80 | — | — | O | O₂ | — | 120 | |
| Exam- | SiO₂ | SiO₂ | S2 | 200 | O | O | O | — | ON | 120 | 1 |
| ple 14 | | | S3 | 200 | — | — | O | O₂ | — | 120 | |

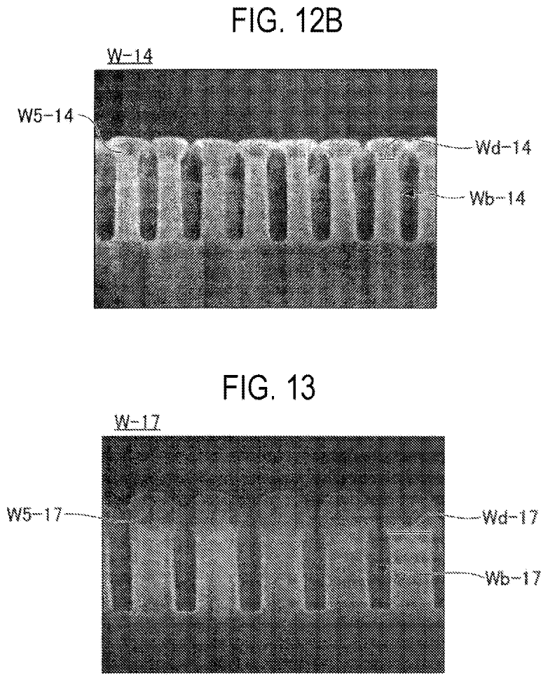

FIG. 12A shows a SEM photograph of a substrate W-13 according to Example 13 after processing. In Example 13, steps S2 and S3 were performed once each under the same conditions as Example 4, except that the temperature of the substrate was changed to 80 degrees C. As a result, a film W5-13 was selectively formed on the protrusion top surfaces Wd-13 among the recesses Wb-13 and the protrusion top surfaces Wd-13.

FIG. 12B shows a SEM photograph of a substrate W-14 according to Example 14 after processing. In Example 14, steps S2 and S3 were performed once each under the same conditions as Example 4, except that the temperature of the substrate was changed to 200 degrees C. As a result, a film W5-14 was selectively formed on the protrusion top surfaces Wd-14 among the recesses Wb-14 and the protrusion top surfaces Wd-14.

As is clear from Examples 13 and 14, it was possible to selectively form films W5 on the protrusion top surfaces Wd at various temperatures of substrates.

### Examples 15 to 16

In Example 15, steps S1 to S3 and S5 were performed by using the film forming apparatus 1 illustrated in FIG. 5 under the processing conditions represented in Table 6, and steps S4 and S6 to S8 were not performed. On the other hand, in Example 16, steps S1 to S5 were performed by using the film forming apparatus 1 illustrated in FIG. 5 under the processing conditions represented in Table 6, and steps S6 to S8 were not performed.

TABLE 6

| | Protru- | | | Tem- | | | | Other | | | |
|---|---|---|---|---|---|---|---|---|---|---|---|
| | sion | Recess | | perature | | | | sup- | | | Number |
| | top | bottom | | [degrees | | | | plied | | Time | of |
| | surface | surface | Steps | C.] | TiCl₄ | H₂ | Ar | gas | RF | [sec] | Cycles |
| Exam- | SiO₂ | SiO₂ | S2 | 130 | O | O | O | — | ON | 30 | 12 |
| ple 15 | | | S3 | 130 | — | — | O | O₂ | — | 60 | |
| Exam- | SiO₂ | SiO₂ | S2 | 130 | O | O | O | — | ON | 30 | 12 |
| ple 16 | | | S3 | 130 | — | — | O | O₂ | — | 60 | |
| | | | S4 | 130 | — | — | O | O₂ | ON | 60 | |

When the film W5 formed on the protrusion top surfaces Wd in Example 15 was etched with an aqueous solution having an HF concentration of 0.5% by mass, the etching rate was 762.8 Å/min. On the other hand, when the film W5 formed on the protrusion top surfaces Wd in Example 16 was etched with an aqueous solution having an HF concentration of 0.5% by mass, the etching rate was 81.3 Å/min. Therefore, it was possible to modify the film W5 by step S5.

### Example 17

In Example 17, steps S1 to S3 and S5 were performed by using the film forming apparatus 1 illustrated in FIG. 5 under the processing conditions represented in Table 7, and steps S4 and S6 to S8 were not performed.

TABLE 7

| | Protru- | | | Tem- | | | | Other | | | |
|---|---|---|---|---|---|---|---|---|---|---|---|
| | sion | Recess | | perature | | | | sup- | | | Number |
| | top | bottom | | [degrees | | | | plied | | Time | of |
| | surface | surface | Steps | C.] | Si₂Cl₆ | H₂ | Ar | gas | RF | [sec] | Cycles |
| Exam- | TiO₂ | TiO₂ | S2 | 130 | O | O | O | — | ON | 60 | 2 |
| ple 17 | | | S3 | 130 | — | — | O | O₂ | ON | 60 | |

FIG. 13 shows a SEM photograph of a substrate W-17 according to Example 17 after processing. In Example 17, unlike Example 1, in step S2, Si₂Cl₆ (HCD) was supplied into the processing container 2 instead of TiCl₄ as the raw material gas. In addition, in step S3, Ar gas and O₂ gas were plasmatized. In addition, steps S2 and S3 were performed twice each. Furthermore, the material of the protrusion top surfaces and the recess bottom surfaces was changed to TiO₂. As a result, a film W5-17 was selectively formed on the protrusion top surfaces Wd-17 among the recesses Wb-17 and the protrusion top surfaces Wd-17. The same results were obtained when the material of the protrusion top surfaces and the recess bottom surfaces was changed to SiO₂.

### Example 18

In Example 18, steps S1 to S3 and S5 were performed by using the film forming apparatus 1 illustrated in FIG. 5 under the processing conditions represented in Table 8, and steps S4 and S6 to S8 were not performed.

TABLE 8

| | Protru- | | | Tem- | | | | Other | | | |
|---|---|---|---|---|---|---|---|---|---|---|---|
| | sion | Recess | | perature | | | | sup- | | | Number |
| | top | bottom | | [degrees | | | | plied | | Time | of |
| | surface | surface | Steps | C.] | SnCl₄ | H₂ | Ar | gas | RF | [sec] | Cycles |
| Exam- | SiO₂ | SiO₂ | S2 | 90 | O | O | O | — | ON | 60 | 1 |
| ple 18 | | | S3 | 90 | — | — | O | O₂ | — | 120 | |

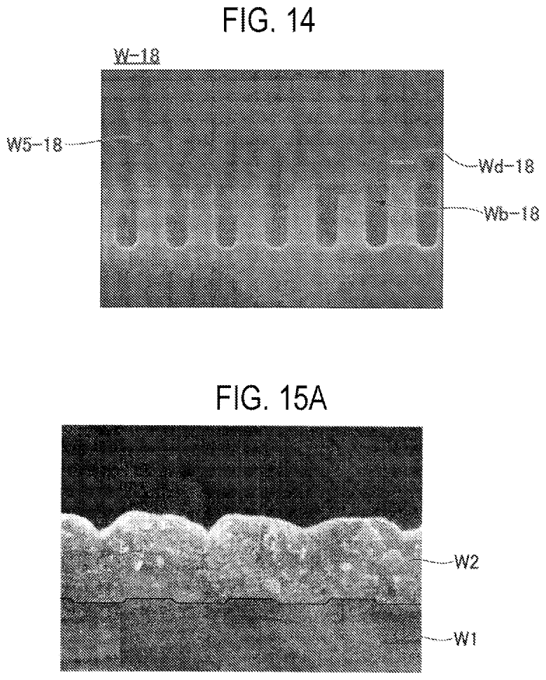

FIG. 14 shows a SEM photograph of a substrate W-18 according to Example 18 after processing. In Example 18, unlike Example 1, in step S2, SnCl₄ was supplied into the processing container 2 instead of TiCl₄ as the raw material gas. As a result, a film W5-18 was selectively formed on the protrusion top surfaces Wd-18 among the recesses Wb-18 and the protrusion top surfaces Wd-18.

As is clear from Examples 17 and 18, it was possible to selectively form films W5 on the protrusion top surfaces Wd by using various raw material gases.

### Example 19

In Example 19, four substrates W having different initial depths A0 were prepared. The initial depths A0 of the four prepared substrates W were 8 nm, 12 nm, 18 nm, and 150 nm, respectively. For the substrate W having an initial depth A0 of 8 nm, 12 nm, or 18 nm, recesses and protrusions were formed by etching silicon wafers. On the other hand, for the substrate having an initial depth A0 of 150 nm, a SiN film and a Si film were formed in that order on the surface of a silicon wafer, and recesses and protrusions were formed by etching the Si film. The SiN film was made to function as an etching stopper film that stops etching.

In Example 19, steps S1 to S5 were performed by using the film forming apparatus 1 illustrated in FIG. 5, and steps S6 to S8 were not performed. In Example 19, the first cycle including steps S2 to S4 was performed 12 times (M=12) under the processing conditions represented in Table 9.

TABLE 9

| | | Tem- | | | | | | | |
|---|---|---|---|---|---|---|---|---|---|
| | | perature | | | | Other | | | |
| | | [degrees | | | | sup-plied | | Time | M or |
| | Steps | C.] | TiCl₄ | H₂ | Ar | gas | RF | [sec] | N |
| Exam- | S2 | 130 | O | O | O | — | ON | 30 | — |
| ple 19 | S3 | 130 | — | — | O | O₂ | — | 60 | |
| | S4 | 130 | — | — | O | O₂ | ON | 60 | |
| | S5 | — | — | — | — | — | — | — | M = 12 |

In Table 9, “O” for various gases means that the various gases were supplied, and “ON” for “RF” means that gases was plasmatized by RF power. The same applies to Tables 10 to 12 and 14, which will be described later.

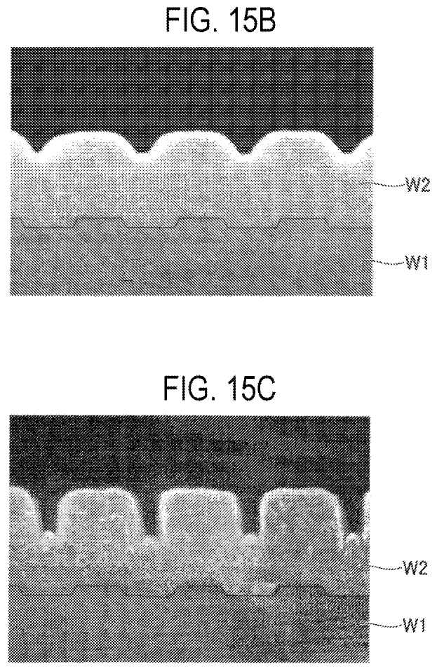

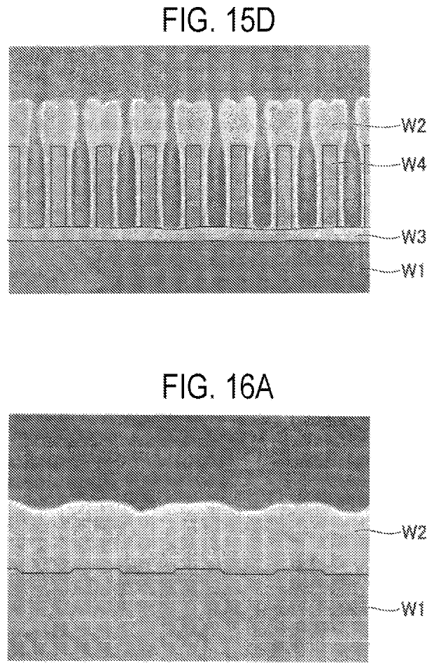

FIGS. 15A to 15D show SEM photographs of the four substrates W obtained in Example 19. In FIGS. 15A to 15D, W1 indicates silicon wafers, and W2 indicates films formed by the first cycle. In addition, in FIG. 15D, W3 indicates a SiN film, and W4 indicates a Si film.

As shown in FIGS. 15A to 15C, when the initial depth A0 was 20 nm or less, the films W2 were also formed on the bottom surfaces and side surfaces of the recesses. However, the thicknesses of the films W2 on the protrusion top surfaces were larger than the thicknesses of the films W2 on the recess bottom surfaces and hence, the steps differences on the substrate surfaces were expanded by the first cycle. In addition, as shown in FIG. 15C, protuberances were sometimes formed on the bottom surfaces of the recesses.

On the other hand, as shown in FIG. 15D, when the initial depth A0 exceeded 100 nm, the film W2 was selectively formed on the protrusion top surfaces with respect to the bottom surfaces and side surfaces of the recesses. The step difference on the substrate surface was expanded by the first cycle.

### Example 20

In Example 20, three substrates W having different initial depths A0 were prepared. The initial depths A0 of the three prepared substrates W were 8 nm, 12 nm, and 18 nm, respectively. These substrates W had recesses and protrusions formed by etching silicon wafers.

In Example 20, steps S1 to S7 were performed by using the film forming apparatus 1 illustrated in FIG. 5, and step S8 was not performed. In Example 20, the second cycle was performed once under the processing conditions represented in Table 10 (N=1). The second cycle included 12 times of the first cycle (M=12) and step S6 performed after the 12 times of the first cycle. The first cycle included steps S2 to S4.

TABLE 10

| | | Tem- | | | | | | | |
|---|---|---|---|---|---|---|---|---|---|
| | | perature | | | | Other | | | |
| | | [degrees | | | | sup-plied | | Time | M or |
| | Steps | C.] | TiCl₄ | H₂ | Ar | gas | RF | [sec] | N |
| Exam- | S2 | 130 | O | O | O | — | ON | 30 | — |
| ple 20 | S3 | 130 | — | — | O | O₂ | — | 60 | |
| | S4 | 130 | — | — | O | O₂ | ON | 60 | |
| | S5 | — | — | — | — | — | — | — | M = 12 |
| | S6 | 130 | — | — | O | ClF₃ | — | 110 | — |
| | S7 | — | — | — | — | — | — | — | N = 1 |

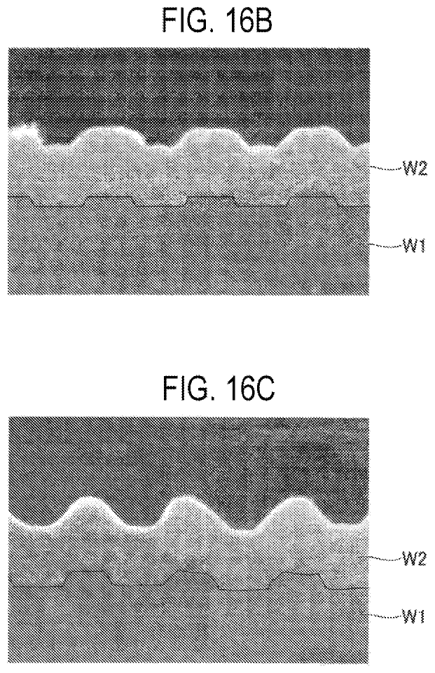

FIGS. 16A to 16C show SEM photographs of the three substrates W obtained in Example 20. In FIGS. 16A to 16C, W1 indicates silicon wafers, and W2 indicates films formed by the second cycle.

As shown in FIGS. 16A to 16C, when the initial depth A0 was 20 nm or less, the films W2 were also formed on the bottom surfaces and side surfaces of the recesses. However, the thicknesses of the films W2 on the protrusion top surfaces were larger than the thicknesses of the films W2 on the recess bottom surfaces and hence, the step differences on the substrate surfaces were expanded by the second cycle.

Furthermore, as is clear from a comparison between FIG. 16C and FIG. 15C, it can be seen that when step S6 is performed, the width of the recesses can be expanded and the protuberances on the recess bottom surfaces can be removed.

### Example 21

In Example 21, three substrates W having different initial depths A0 were prepared. The initial depths A0 of the three prepared substrates W were 8 nm, 12 nm, and 18 nm, respectively. These substrates W had recesses and protrusions formed by etching silicon wafers.

In Example 21, steps S1 to S7 were performed by using the film forming apparatus 1 illustrated in FIG. 5, and step S8 was not performed. In Example 21, the second cycle was performed twice under the processing conditions represented in Table 11 (N=2). The second cycle included 12 times of the first cycle (M=12) and step S6 performed after the 12 times of the first cycle. The first cycle included steps S2 to S4.

TABLE 11

| | | Tem- | | | | | | | |
|---|---|---|---|---|---|---|---|---|---|
| | | perature | | | | Other | | | |
| | | [degrees | | | | sup-plied | | Time | M or |
| | Steps | C.] | TiCl₄ | H₂ | Ar | gas | RF | [sec] | N |
| Exam- | S2 | 130 | O | O | O | — | ON | 30 | — |
| ple 21 | S3 | 130 | — | — | O | O₂ | — | 60 | |
| | S4 | 130 | — | — | O | O₂ | ON | 60 | |
| | S5 | — | — | — | — | — | — | — | M = 12 |
| | S6 | 130 | — | — | O | ClF₃ | — | 110 | — |
| | S7 | — | — | — | — | — | — | | N = 2 |

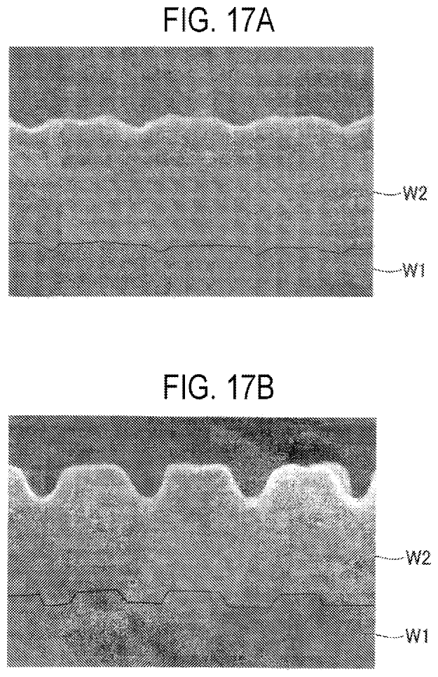

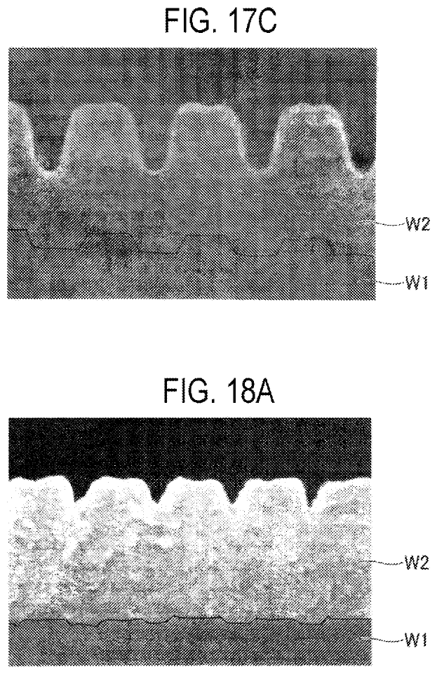

FIGS. 17A to 17C show SEM photographs of the three substrates W obtained in Example 21. In FIGS. 17A to 17C, W1 indicates silicon wafers, and W2 indicates films formed by the second cycle.

As shown in FIGS. 17A to 17C, when the initial depth A0 was 20 nm or less, the films W2 were also formed on the bottom surfaces and side surfaces of the recesses. However, since the thicknesses of the films W2 on the protrusion top surfaces were larger than the thicknesses of the films W2 on the recess bottom surfaces and hence, the step differences on the substrate surfaces were expanded by the second cycle.

Furthermore, as is clear from a comparison between FIG. 17C and FIG. 15C, it can be seen that when step S6 is performed, the width of the recesses can be expanded and the protuberances on the recess bottom surfaces can be removed.

### Example 22

In Example 22, four substrates W having different initial depths A0 were prepared. The initial depths A0 of the four prepared substrates W were 8 nm, 12 nm, 18 nm, and 150 nm, respectively. For the substrates W having an initial depth A0 of 8 nm, 12 nm, or 18 nm, recesses and protrusions were formed by etching silicon wafers. On the other hand, for the substrate having an initial depth A0 of 150 nm, a SiN film and a Si film were formed in that order on the surface of a silicon wafer, and recesses and protrusions were formed by etching the Si film. The SiN film was made to function as an etching stopper film that stops etching.

In Example 22, steps S1 to S7 were performed by using the film forming apparatus 1 illustrated in FIG. 5, and step S8 was not performed. In Example 22, the second cycle was performed three times under the processing conditions represented in Table 12 (N=3). The second cycle included 12 times of the first cycle (M=12) and step S6 performed after the 12 times of the first cycle. The first cycle included steps S2 to S4.

TABLE 12

| | | Tem- | | | | | | | |
|---|---|---|---|---|---|---|---|---|---|
| | | perature | | | | Other | | | |
| | | [degrees | | | | sup-plied | | Time | M or |
| | Steps | C.] | TiCl₄ | H₂ | Ar | gas | RF | [sec] | N |
| Exam- | S2 | 130 | O | O | O | — | ON | 30 | — |
| ple 22 | S3 | 130 | — | — | O | O₂ | — | 60 | |
| | S4 | 130 | — | — | O | O₂ | ON | 60 | |
| | S5 | — | — | — | — | — | — | — | M = 12 |
| | S6 | 130 | — | — | O | ClF₃ | — | 110 | — |
| | S7 | — | — | — | — | — | — | — | N = 3 |

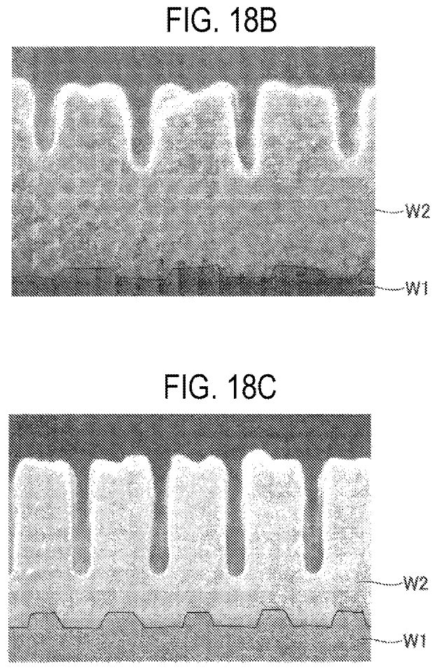

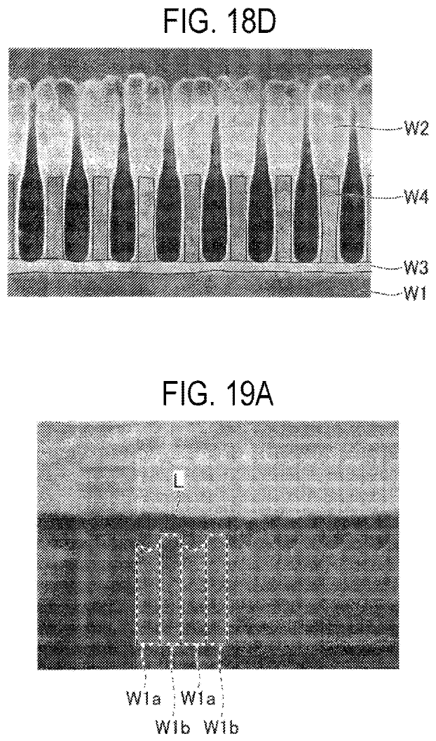

FIGS. 18A to 18D show SEM photographs of the four substrates W obtained in Example 22. In FIGS. 18A to 18D, W1 indicates silicon wafers, and W2 indicates films formed by the second cycle. In addition, in FIG. 18D, W3 indicates a SiN film, and W4 indicates a Si film.

As shown in FIGS. 18A to 18C, when the initial depth A0 was 20 nm or less, the films W2 were also formed on the bottom surfaces and side surfaces of the recesses. However, the thicknesses of the films W2 on the protrusion top surfaces were larger than the thicknesses of the films W2 on the recess bottom surfaces and hence, the step differences on the substrate surfaces were expanded by the second cycle.

Furthermore, as is clear from a comparison between FIG. 18C and FIG. 15C, it can be seen that when step S6 is performed, the width of the recesses can be expanded and the protuberances on the recess bottom surfaces can be removed.

On the other hand, as shown in FIG. 18D, when the initial depth A0 exceeded 100 nm, the film W2 was selectively formed on the protrusion top surfaces with respect to the bottom surfaces and side surfaces of the recesses. The step difference on the substrate surface was expanded by the second cycle while the SiN film W3 remained exposed in the recess bottom surfaces.

### Step Differences of Substrates Obtained in Examples 19 to 22

Table 13 represents the sizes of step differences of the substrates obtained in Examples 19 to 22 (however, in all of Examples 19 to 22, the initial depth of the recesses Wb was 18 nm) in comparison with each other. The sizes of the step differences are represented by the depths A of the recesses Wb.

TABLE 13

| | | | Change in step |
|---|---|---|---|
| | Step difference | Step difference | difference before |
| | before processing | after processing | and after processing |
| | [nm] | [nm] | [nm] |
| Example 19 | 18 | 39 | 21 |
| Example 20 | 18 | 28 | 10 |
| Example 21 | 18 | 56 | 38 |
| Example 22 | 18 | 132 | 114 |

As is clear from a comparison of Examples 20 to 22 in Table 13, it can be seen that when the second cycle is repeatedly performed, it is possible to expand a step difference while securing the width B of recesses Wb. In addition, the reason why the step difference in Example 20 is smaller than that in Example 19 is that the film W2 was etched in Example 20.

### Example 23

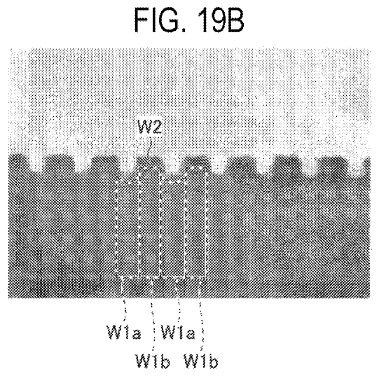

In Example 23, steps S1 to S3 and S5 were performed by using the film forming apparatus 1 illustrated in FIG. 5 under the processing conditions represented in Table 14, and steps S4 and S6 to S8 were not performed. In Example 23, before substrates W were loaded into the processing container 2 illustrated in FIG. 5, recesses and protrusions were formed in advance on the substrate surfaces Wa. Specifically, as shown in FIGS. 19A and 19B, recesses and protrusions were formed by selectively etching a SiO₂ layer W1a among a SiO₂ layer W1a and a SiN layer W1b. The initial depth of the recesses was 30 nm.

TABLE 14

| | | Tem- | | | | | | |
|---|---|---|---|---|---|---|---|---|
| | | perature | | | | Other | | |
| | | [degrees | | | | sup-plied | | Time |
| | Steps | C.] | TiCl₄ | H₂ | Ar | gas | RF | [sec] |
| Exam- | S2 | 130 | O | O | O | — | ON | 120 |
| ple 23 | S3 | 130 | — | — | O | O₂ | — | 120 |

FIGS. 19A and 19B show SEM photographs of the substrate according to Example 23. As shown in FIG. 19A, the liquid L was supplied to the substrate surface Wa in step S2. The liquid L covered not only the recesses but also the protrusions, and the liquid level of the liquid L was horizontal. As shown in FIG. 19B, when step S3 was performed following step S2, the liquid L flowed to expand the step difference, and a film W2 was formed from the liquid L. Therefore, it can be seen that even if the number of times of step S3 is one, the step difference can be expanded.

Regarding the above-described embodiment, the following appendices are disclosed.

### Appendix 1

A film forming method including:
(A) supplying a liquid to the surface of a substrate including a recess and a protrusion, which are adjacent to each other, on the surface;
(B) supplying a processing gas that chemically changes the liquid to the surface of the substrate to move the liquid from the recess to the protrusion by a reaction between the liquid and the processing gas and to form a film on the top surface of the protrusion, thereby expanding a step difference on the surface; and
(C) etching a portion of the film.

### Appendix 2

The film forming method set forth in Appendix 1, wherein a first cycle including the process of (A) and the process of (B) is performed M times (M is an integer of 1 or more), and the process of (C) is performed after the M times of the first cycle.

### Appendix 3

The film forming method set forth in Appendix 2, wherein a second cycle including the M times of the first cycle and the process of (C) performed after the M times of the first cycle is performed N times (N is an integer of 1 or more).

### Appendix 4

The film forming method set forth in Appendix 3, further including etching the film after performing the second cycle N times to expose, on a bottom surface of the recess, a material different from the film.

### Appendix 5

The film forming method set forth in any one of Appendices 1 to 4, wherein before performing the process of (A), the step difference formed on the surface of the substrate is 20 nm or less.

### Appendix 6

The film forming method set forth in any one of Appendices 1 to 5, wherein the liquid is a halide.

### Appendix 7

The film forming method set forth in Appendix 6, wherein the process of (A) includes forming the liquid by a reaction between a raw material gas that is a raw material for the halide and a reaction gas that reacts with the raw material gas.

### Appendix 8

The film forming method set forth in any one of Appendices 1 to 5, wherein the liquid is a liquid polymer.

### Appendix 9

The film forming method set forth in Appendix 8, wherein the liquid is synthesized in a processing container that accommodates the substrate, and is supplied to the recess of the substrate.

### Appendix 10

The film forming method set forth in any one of Appendices 1 to 9, wherein the processing gas that chemically changes the liquid in the process of (B) contains an element that is introduced into the liquid.

### Appendix 11

The film forming method set forth in Appendix 10, wherein the processing gas that chemically changes the liquid includes an oxygen-containing gas.

### Appendix 12

The film forming method set forth in Appendix 10, wherein the processing gas that chemically changes the liquid includes a nitrogen-containing gas.

### Appendix 13

The film forming method set forth in Appendix 10, wherein the processing gas that chemically changes the liquid includes a hydride gas.

### Appendix 14

The film forming method according to any one of Appendices 1 to 9, wherein the processing gas that chemically changes the liquid degasses an element constituting the liquid.

### Appendix 15

The film forming method set forth in Appendix 14, wherein the processing gas that chemically changes the liquid includes a reducing gas.

### Appendix 16

The film forming method set forth in Appendix 15, wherein the reducing gas is hydrogen gas or deuterium gas.

### Appendix 17

The film forming method set forth in any one of Appendices 1 to 16, wherein the process of (B) includes plasmatizing the processing gas that chemically changes the liquid.

### Appendix 18

The film forming method set forth in any one of Appendices 1 to 17, wherein the process of (C) includes etching a portion of the film with an etching gas.

### Appendix 19

The film forming method set forth in any one of Appendices 1 to 18, further including modifying the film after the process of (B) and before the process of (C).

1. A film forming method comprising:
(A) supplying a liquid to a surface of a substrate including a recess and a protrusion, which are adjacent to each other, on the surface;
(B) supplying a processing gas that chemically changes the liquid to the surface of the substrate to move the liquid from the recess to the protrusion by a reaction between the liquid and the processing gas and to form a film on the top surface of the protrusion, thereby expanding a step difference on the surface; and
(C) etching a portion of the film.

2. The film forming method of claim 1, wherein a first cycle comprising the processes of (A) and (B) is performed M times (M is an integer of 1 or more), and the process of (C) is performed after the M times of the first cycle.

3. The film forming method of claim 2, wherein a second cycle comprising the M times of the first cycle and the process of (C) performed after the M times of the first cycle is performed N times (N is an integer of 1 or more).

4. The film forming method of claim 3, further comprising:
etching the film after performing the second cycle N times to expose, on a bottom surface of the recess, a material different from the film.

5. The film forming method of claim 1, wherein before performing the process of (A), the step difference formed on the surface of the substrate is 20 nm or less.

6. The film forming method of claim 1, wherein the liquid is a halide.

7. The film forming method of claim 6, wherein the process of (A) comprises forming the liquid by a reaction between a raw material gas that is a raw material for the halide and a reaction gas that reacts with the raw material gas.

8. The film forming method of claim 1, wherein the liquid is a liquid polymer.

9. The film forming method of claim 8, wherein the liquid is synthesized in a processing container that accommodates the substrate, and is supplied to the recess of the substrate.

10. The film forming method of claim 1, wherein the processing gas that chemically changes the liquid in the process of (B) contains an element that is introduced into the liquid.

11. The film forming method of claim 10, wherein the processing gas that chemically changes the liquid comprises an oxygen-containing gas.

12. The film forming method of claim 10, wherein the processing gas that chemically changes the liquid comprises a nitrogen-containing gas.

13. The film forming method of claim 10, wherein the processing gas that chemically changes the liquid comprises a hydride gas.

14. The film forming method of claim 1, wherein the processing gas that chemically changes the liquid degasses an element constituting the liquid.

15. The film forming method of claim 14, wherein the processing gas that chemically changes the liquid comprises a reducing gas.

16. The film forming method of claim 15, wherein the reducing gas is hydrogen gas or deuterium gas.

17. The film forming method of claim 1, wherein the process of (D) B comprises plasmatizing the processing gas that chemically changes the liquid.

18. The film forming method of claim 1, wherein the process of (C) comprises etching a portion of the film with an etching gas.

19. The film forming method of claim 1, further comprising:
modifying the film after the process of (B) and before the process of (C).

20. A film forming apparatus comprising:
a processing container;
a holder configured to horizontally hold a substrate with a surface having a recess and a protrusion, which are adjacent to each other, within the processing container with the surface facing upward;
a gas supplier configured to supply, to the surface of the substrate held by the holder, a raw material gas, a reaction gas that reacts with the raw material gas, a processing gas that chemically changes a liquid formed by the reaction between the raw material gas and the reaction gas, and an etching gas; and
a controller configured to control the gas supplier,
wherein the controller is configured to perform:
supplying the liquid formed by the reaction between the raw material gas and the reaction gas to the surface of the substrate;
supplying the processing gas to the surface of the substrate to move the liquid from the recess to the protrusion by a reaction between the liquid and the processing gas and to form a film on the top surface of the protrusion, thereby expanding a step difference on the surface; and
etching a portion of the film with the etching gas.
